(19) United States
(12) Patent Application Publication
(10) Pub. No.: US 2021/0010155 A1
(43) Pub. Date: Jan. 14, 2021

(54) SEMICONDUCTOR CRYSTAL GROWTH APPARATUS

(71) Applicant: Zing Semiconductor Corporation, Shanghai (CN)

(72) Inventors: Weimin Shen, Shanghai (CN); Gang Wang, Shanghai (CN); Xianliang Deng, Shanghai (CN); Hanyi Huang, Shanghai (CN); Wee Teck Tan, Shanghai (CN)

(21) Appl. No.: 16/904,563

(22) Filed: Jun. 18, 2020

(30) Foreign Application Priority Data
Jun. 18, 2019 (CN) 201910527727.8

(51) Int. Cl. C30B 15/30; C30B 29/06

(52) U.S. Cl. CPC C30B 15/30; C30B 29/06

(57) ABSTRACT

The present invention provides a semiconductor crystal growth apparatus, which comprises a furnace body, a crucible, a pulling device, a deflector, and a magnetic field applying device. The crucible is disposed inside the furnace body for containing silicon melt. The pulling device is disposed on the top of the furnace body for pulling a silicon ingot from the silicon melt. The deflector is in a barrel shape and is disposed in the furnace body in a vertical direction, and the pulling device pulls the silicon ingot in a vertical direction and through the deflector. The magnetic field applying device is configured to apply a magnetic field to the silicon melt in the crucible, in which the distance between the bottom of the deflector and the liquid level of the silicon melt in the direction of the magnetic field is less than that between the bottom of the deflector and the silicon melt in the direction perpendicular to the direction of the magnetic field.

### CROSS-REFERENCE TO RELATED APPLICATIONS

This application claims priority to P.R.C. Patent Application No. 201910527727.8 titled “Semiconductor crystal growth apparatus” filed on Jun. 18, 2019, with the State Intellectual Property Office of the People's Republic of China (SIPO).

### TECHNICAL FIELD

The present disclosure relates to a semiconductor crystal growth apparatus.

### BACKGROUND

The Czochralski Process (CZ) method is an important method for preparing single crystal silicon in semiconductors and solar energy manufacturing industries. The high-purity silicon material placed in a crucible is heated and melted by a thermal field composed of a carbon material, and then the seed crystal is immersed in a single ingot is finally obtained in the melt through a series of processes such as introduction, shouldering, equal diameter, finishing, and cooling etc.

During the crystal growth of the single crystal silicon in semiconductors and solar energy manufacturing industries by using CZ method, the temperature distribution of the crystal and the silicon melt affect the quality and the growth speed of the crystal. During the CZ crystal growth, due to the presence of thermal convection in the silicon melt, the distribution of trace impurities is uneven, and growth stripes are formed. Therefore, in the process of crystal pulling, how to suppress the thermal convection and temperature fluctuations of the silicon melt is a matter of widespread concern.

The crystal growth technology under a magnetic field generating device (MCZ) applies a magnetic field to a silicon melt as a conductor to make the silicon melt subject to the Lorentz force in the opposite direction of its movement, which impedes convection in the silicon melt, increases the viscosity in the silicon melt, and reduces impurities such as oxygen, boron, and aluminum from the quartz crucible into the silicon melt, and then into the crystal. Eventually, the grown silicon crystal can have a controlled oxygen content ranging from low to high, which reduces impurity fringes, such that this method is widely used in semiconductor crystal growth process. A typical MCZ technology is a magnetic field crystal growth (HMCZ) technology, which applies a magnetic field to the semiconductor melt and is widely applicable to the growth of large-size and high-demand semiconductor crystals.

In the crystal growth technology under the magnetic field device (HMCZ), a furnace body, a thermal field, a crucible, and a silicon crystal of the crystal growth are all as symmetrical as possible in the circumferential direction, and the rotation of the crucible and the crystal makes the temperature distribution in the circumferential direction tend to be uniform. However, the magnetic field lines of the magnetic field applied during the magnetic field application process pass from one end parallel to the silicon melt in the quartz crucible to the other, and Lorentz force generated by the rotating silicon melt is different everywhere in the circumferential direction, so the flow and temperature distribution of the silicon melt are not uniform in the circumferential direction.

As shown in FIGS. 1A and 1B, that illustrate schematic diagrams of a temperature distribution below an interface between a crystal and a silicon melt of a crystal grown in a semiconductor crystal growth apparatus. FIG. 1A shows a diagram of the measured points distributed on the horizontal surface of the silicon melt in the crucible, in which one point is measured every θ=45° at 25 mm below the silicon melt liquid level and at a distance L=250 mm from the center. FIG. 1B is a curve of temperature distribution obtained by simulation calculation and measured along various points at an angle θ with the X axis in FIG. 1A, in which the solid line represents the temperature distribution diagram obtained by simulation calculation, and the dot diagram represents the temperature distribution diagram obtained by a measured method. In FIG. 1A, arrow A shows that the direction of rotation of the crucible is counterclockwise, and arrow B shows that the direction of the magnetic field crosses the diameter of the crucible along the Y-axis direction. As can be seen from FIG. 1B, during the process of the semiconductor crystal growth, whether the data obtained from the simulation calculation or the measured method reflects the temperature change below the interface between a crystal and a silicon melt liquid level fluctuates on the circumference as the angle changes.

In the equation, a potential of the phase transition from silicon melt to silicon crystal is represented by LQ, thermal conductivities of the silicon crystal and the silicon melt are represented by Kc and Km, respectively, in which Kc, Km and LQ are physical parameters of silicon materials, a crystallization speed of the crystal in the stretching direction is represented by PS, which is approximately the pulling speed of the silicon crystal, and temperature gradients of the silicon crystal and the silicon melt at the interface (dT/dZ) are represented by Gc and Gm, respectively. Because, during the growth of the semiconductor crystal, the temperature below the cross section of the silicon crystal and the silicon melt exhibits periodic fluctuation with the change of the circumferential angle, that is, the Gc and Gm of the temperature gradient (dT/dZ) of the silicon crystal and the silicon melt as the interface exhibit fluctuation. Therefore, the crystallization speed PS of the crystal in the circumferential angle direction exhibits periodic fluctuations, which is not conducive to the control of the crystal growth quality.

For this reason, it is necessary to propose a new semiconductor crystal growth device to solve the problems in the prior art.

### SUMMARY

A series of simplified forms of concepts are introduced in the summary section, which will be explained in further detail in the detailed description section. The summary of the present invention does not mean trying to define the key features and necessary technical features of the claimed technical solution, let alone trying to determine the protection scope of the claimed technical solution.

In order to solve the problems in the prior art, the invention provides a semiconductor crystal growth apparatus, comprises:
a furnace body;
a crucible, which is disposed inside the furnace body for containing a silicon melt;
a pulling device, which is disposed on the top of the furnace body for pulling a silicon ingot from the silicon melt;
a deflector, which is in a barrel shape and is disposed in the furnace body in a vertical direction, and the pulling device pulls the silicon ingot in a vertical direction and through the deflector; and
a magnetic field applying device, which is configured to apply a horizontal magnetic field to the silicon melt in the crucible;
wherein the distance between the bottom of the deflector and the liquid level of the silicon melt in the direction of the magnetic field is less than that between the bottom of the deflector and the silicon melt in the direction perpendicular to the direction of the magnetic field.

In accordance with some embodiments, the bottom of the deflector has a wave-shaped surface protruding downward.

In accordance with some embodiments, in the direction of the magnetic field, the bottom of the deflector is located on a wave trough of the wave-shaped surface, such that the distance between the bottom of the deflector and the liquid level of the silicon melt in the direction of the magnetic field is minimum, and in the direction perpendicular to the direction of the magnetic field, the bottom of the deflector is located on a wave crest of the wave-shaped surface, such that the distance between the bottom of the deflector and the liquid level of the silicon melt in the direction of the magnetic field is maximum.

In accordance with some embodiments, the distance between the wave trough of the wave-shaped surface and the liquid level of the silicon melt is between 10-50 mm, and the distance between the wave crest of the wave-shaped surface and the liquid level of the silicon melt is between 30-80 mm.

In accordance with some embodiments, the deflector comprises a tuning device, which is configured to tune the distance between the deflector and the liquid level of the silicon melt.

In accordance with some embodiments, the deflector comprises an inner cylinder, an outer cylinder and a heat-insulation material, in which a bottom of the outer cylinder is extended below a bottom of the inner cylinder and is closed with the bottom of the inner cylinder to form a cavity between the inner cylinder and the outer cylinder, and the heat-insulation material is disposed in the cavity. The tuning device comprises an insert part, in which the inset part comprises a protruding portion and an insert portion, the insert portion is inserted into the bottom of the outer cylinder and extended to the location between the portion below the bottom of the inner cylinder and the bottom of the inner cylinder, and the protruding portion is extended exceeding the bottom of the inner cylinder.

In accordance with some embodiments, the tuning device comprises at least two sections disposed along a direction perpendicular to the direction of the magnetic field.

In accordance with some embodiments, the protruding portion is arranged as a ring.

In accordance with some embodiments, the bottom of the ring has a wave-shaped surface protruding downward.

According to the semiconductor crystal growth apparatus provided in the present invention, by setting the distance between the bottom of the deflector and the silicon ingot in the direction of the magnetic field less than that between the bottom of the deflector and the silicon ingot in the direction perpendicular to the direction of the magnetic field, the temperature distribution of the silicon melt below the interface between the silicon ingot and the silicon melt is tuned, such that the problem of fluctuations in the temperature distribution of the silicon melt below the interface between the semiconductor crystal and the liquid level of the silicon melt resulted from the applied magnetic field can be tuned during the growth of the semiconductor crystal, and effectively improve the uniformity of the temperature distribution of the silicon melt, thereby improving the uniformity of the crystal growth rate and the quality of crystal pulling.

### BRIEF DESCRIPTION OF THE DRAWINGS

Exemplary embodiments will be more readily understood from the following detailed description when read in conjunction with the appended drawings, in which:

FIGS. 1A and 1B are schematic diagrams of the temperature distribution below the interface between the grown semiconductor crystal and the silicon melt in a semiconductor crystal growth apparatus.

FIG. 2 is a schematic structural diagram of a semiconductor crystal growth apparatus.

FIG. 3A is a schematic diagram of arrangement of cross-sectional positions of a crucible, a deflector, and a silicon ingot in a semiconductor crystal growth apparatus.

FIG. 3B is a schematic diagram of the change in the distance between the bottom of the deflector and the liquid level of the silicon melt in the semiconductor crystal growth apparatus according to an embodiment of the present invention as the angle α in FIG. 3A changes.

FIG. 3C is a schematic diagram of the heat radiated from the liquid level of the silicon melt to the deflector in the semiconductor crystal growth apparatus according to an embodiment of the present invention as the angle α in FIG. 3A changes.

FIG. 4 is a schematic structural diagram of the deflector in the semiconductor crystal growth apparatus.

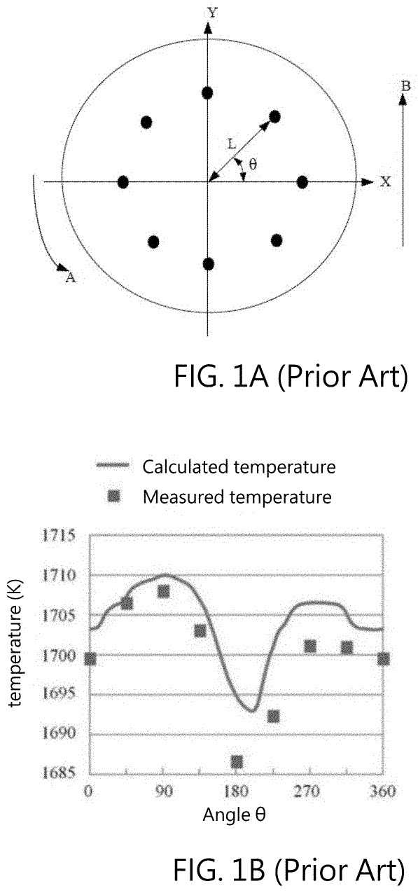

### DETAILED DESCRIPTION

In the following description, numerous specific details are given to provide a more thorough understanding of the present invention. However, it will be apparent to one skilled in the art that the present invention may be practiced without one or more of these details. In other examples, in order to avoid confusion with the present invention, some technical features known in the art are not described.

For a thorough understanding of the present invention, a detailed description will be provided in the following description to illustrate the method according to the present invention. Obviously, the implementation of the present invention is not limited to the specific details familiar to those skilled in the semiconductor field. The preferred embodiments of the present invention are described in detail below. However, in addition to these detailed descriptions, the present invention may have other embodiments.

It should be noted that terminology used herein is for the purpose of describing particular embodiments only and is not intended to limit the exemplary embodiments according to the present invention. As used herein, the singular forms are intended to comprise the plural forms as well, unless the context clearly indicates otherwise. In addition, it should also be understood that when the terms “including” and/or “including” are used in this specification, they indicate the presence of stated features, integers, steps, operations, elements and/or components, but do not exclude the presence or Add one or more other features, wholes, steps, operations, elements, components, and/or combinations thereof.

Now, exemplary embodiments according to the present invention will be described in more detail with reference to the accompanying drawings. These exemplary embodiments may, however, be embodied in many different forms and should not be construed as limited to the embodiments set forth herein. It should be understood that these embodiments are provided so that this disclosure will be thorough and complete, and will fully convey the concept of the exemplary embodiments to those skilled in the art. In the drawings, the thicknesses of layers and regions are exaggerated for the sake of clarity, and the same elements are denoted by the same reference numerals, and their descriptions will be omitted.

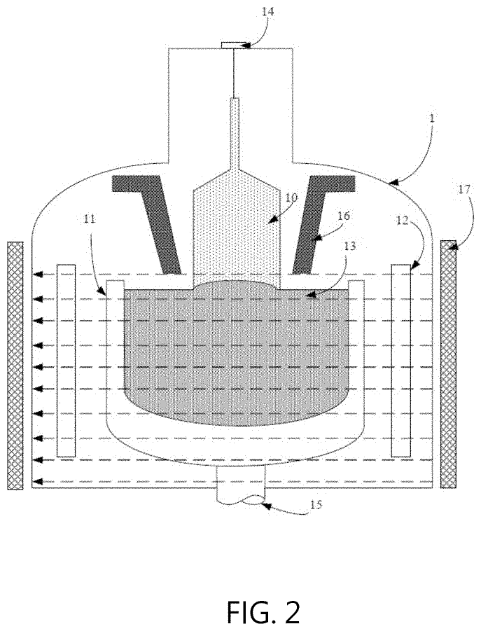

Referring to FIG. 2, FIG. 2 is a schematic structural diagram of a semiconductor crystal growth apparatus. The semiconductor crystal growth apparatus may comprise a furnace body 1, a crucible 11, and a heater 12. The crucible 11 may be disposed in the furnace body 1, the heater 12 may be disposed outside the crucible 11 for heating the crucible 11, and the crucible 11 may contain a silicon melt 13. The crucible 11 may be composed of a graphite crucible and a quartz crucible sheathed in the graphite crucible, and the graphite crucible is heated by the heater to melt the polycrystalline silicon material in the quartz crucible to form a silicon melt. Each quartz crucible is used for one lot of semiconductor growth process, and each graphite crucible is used for multiple lots of semiconductor growth process.

A pulling device 14 may be disposed on the top of the furnace body 1. Driven by the pulling device 14, a seed crystal may be pulled and pulled out of a silicon ingot 10 from the liquid level of the silicon melt, and a heat shield device is provided around the silicon ingot 10. For example, as shown in FIG. 2, the heat shield device comprises a deflector 16, which is provided in a conical barrel type. As a heat shield device, it is used to isolate the thermal radiation generated by the silicon melt on the crystal surface in the quartz crucible and the crucible during the crystal growth process to increase the cooling rate and axial temperature gradient of the silicon ingot, and increase the number of crystal growth. On the other hand, it affects the thermal field distribution on the surface of the silicon melt, and avoids the axial temperature gradient of the center and edge of the silicon ingot from being too large, to ensure stable growth between the silicon ingot and the liquid level of the silicon melt. At the same time, the guide tube 16 is also used to guide the inert gas introduced from the upper part of the crystal growth furnace, so that it passes through the surface of the silicon melt at a relatively high flow rate, so as to achieve the effect of controlling the oxygen content and impurity content in the crystal. During the growth of the semiconductor crystal, driven by the pulling device 14, the silicon ingot 10 passes vertically through the deflector 16.

In order to achieve stable of the silicon ingot, a driving device 15 for driving the crucible 11 to rotate and move up and down may be provided at the bottom of the furnace body 1. The driving device 15 may drive the crucible 11 to keep rotating during the crystal pulling process to reduce the asymmetry of the heat of the silicon melt for equal-diameter growth of the silicon ingot.

In order to hinder the convection of the silicon melt, the viscosity of the silicon melt is increased, and oxygen, boron, aluminum and other impurities are reduced from the quartz crucible into the silicon melt, and then into the crystal, so that the grown silicon crystal can have a controlled oxygen content ranging from low to high with reduced impurity fringes. The semiconductor crystal growth apparatus may further comprise a magnetic field applying device 17 provided outside the furnace body 1 to apply a magnetic field to the silicon melt in the crucible 11.

Since the lines of magnetic force applied by the magnetic field applying device 17 pass through the silicon melt in the crucible 11 in parallel from one end to the other end (see the dashed arrow in FIG. 2). The Lorentz force generated by the rotating silicon melt is different in the circumferential direction, so the flow of silicon melt is inconsistent with the temperature distribution in the circumferential direction, in which the temperature along the direction of the magnetic field is higher than that along the direction perpendicular to the direction of the magnetic field. The inconsistency between the flow of silicon melt and the temperature is expressed as the temperature below the cross section of the semiconductor crystal and the silicon melt fluctuates with the change in angle, so that the crystallization speed PS of the crystal exhibits periodic fluctuations, and the semiconductor growth speed is uneven on the circumference, which is not conducive to the control of the growth quality of semiconductor crystals.

For this reason, in the semiconductor crystal growth apparatus of the present invention, the deflector 16 is provided with different distances between the bottom and the liquid level of the silicon melt.

Specifically, the distance between the bottom of the deflector and the silicon ingot in the direction of the magnetic field is smaller than that between the bottom of the deflector and the silicon ingot in the direction perpendicular to the direction of the magnetic field distance. At larger distances, since the liquid level of the silicon melt is far away from the deflector, the heat radiated from the liquid level of the silicon melt to the deflector is small; at smaller distances, due to the liquid level of the silicon melt is close to the deflector, the heat radiated from the liquid level of the silicon melt to the deflector is large. Therefore, the reduced temperature of the liquid level of the silicon melt at the larger distance is less than that at the smaller distance, which compensates for the problems of the temperature in the direction of the magnetic field is higher than the temperature perpendicular to the direction of application caused by the influence of the applied magnetic field on the flow of silicon melt. Accordingly, the distance between the bottom of the deflector and the silicon ingot is set to tune the temperature distribution of the silicon melt below the interface between the silicon ingot and the silicon melt, such that fluctuations in the temperature distribution of the silicon melt resulting from the applied magnetic field can be tuned. Therefore, the uniformity of the temperature distribution of the liquid level of the silicon melt is effectively improved, thereby the uniformity of the crystal growth rate and the quality of the crystal pulling are improved.

At the same time, due to the different distances between the bottom of the deflector and the liquid level of the silicon melt, so that at a larger distance, the pressure flow rate from the top of the furnace body reversed to the liquid level of the silicon melt via the deflector is increased, and the shear force on the liquid level of the silicon melt is increased. At the small distance, the pressure flow rate from the top of the furnace body reversed to the liquid level of the silicon melt via the deflector is decreased, and the shear force on the liquid level of the silicon melt is decreased. Accordingly, the flow structure of the silicon melt is further tuned by setting the distance between the bottom of the deflector and the silicon ingot to make the flow state of the silicon melt along the circumferential direction more uniform. This further improves the uniformity of the crystal growth rate and improves the crystal pulling quality. At the same time, through changing the flow state of the silicon melt, the oxygen content distribution in the grown semiconductor crystal is uniform, the uniformity of the oxygen content distribution in the crystal is improved, and the crystal growth defects are reduced.

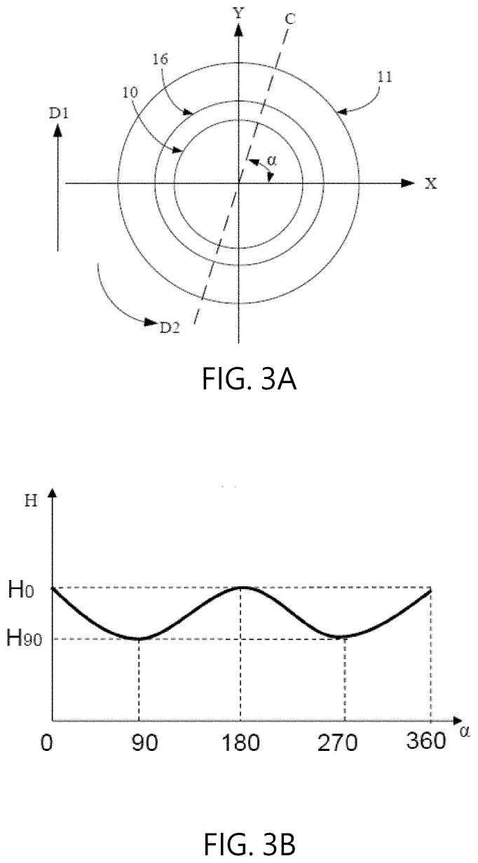

In one embodiment according to the present invention, the bottom of the deflector 16 may have a wave-shaped surface protruding downward. Referring to FIGS. 3A and 3B, FIG. 3A is a schematic diagram of arrangement of cross-sectional positions of a crucible, a deflector, and a silicon ingot in the semiconductor crystal growth apparatus. FIG. 3B is a schematic diagram of the change in the distance between the bottom of the deflector and the liquid level of the silicon melt in the semiconductor crystal growth apparatus according to an embodiment of the present invention as the angle α in FIG. 3A changes.

As shown in FIG. 3A, in the plan view, the cross-sections of the crucible 11, the deflector 16, and the silicon ingot 10 are arranged concentrically. Arrow D1 shows the direction of the magnetic field, and arrow D2 shows the direction of rotation of the crucible 11. It can be seen from FIG. 3B that the distance H between the bottom of the deflector and the liquid level of the silicon melt is wavy as the angle α changes in FIG. 3A. When α is 90° or 270° (that is, in the direction of the magnetic field), H90 between the bottom of the deflector and the liquid level of the silicon melt is located at the wave trough (i.e. the smallest). When α is 0° or 180° (i.e. in the direction perpendicular to the direction of the magnetic field), the H0 between the bottom of the deflector and the liquid level of the silicon melt is located at the wave crest (i.e. the largest). In this arrangement, the distance between the bottom of the deflector and the liquid level of the silicon melt exhibits a slow and gradual change with the change of the angle α, such that the heat radiated from the liquid level of the silicon melt to the bottom of the deflector exhibits a slow and gradual change in a wavy shape corresponding to its changing trend. As shown in FIG. 3C, when α is 90° or 270° , the heat Q90 radiated from the liquid level of the silicon melt to the bottom of the deflector is located at the wave crest (i.e. the maximum); when α is 0° or 180°, the heat Q90 radiated from the liquid level of the silicon melt to the bottom of the deflector is located at the wave trough (i.e. the smallest).

Correspondingly, due to the heat radiated from the liquid level of the silicon melt to the bottom of the deflector changes as shown in FIG. 3C, the decrease in the temperature of the liquid level of the silicon melt changes as shown in FIG. 3C, that is in line with the law of temperature change at the lower position between the interface between the silicon melt and the silicon ingot obtained during the simulation and measurement. Therefore, the effect of fully tuning the temperature at the lower position between the interface between the silicon melt and the silicon ingot is achieved, so that the temperature of the liquid level of the silicon melt is more uniform.

In the above example of the wave-shaped surface of the bottom of the deflector protruding downward, exemplarily, the distance from the wave trough to the liquid level of the silicon melt is between 10-50 mm, and the distance from the wave crest to the liquid level of the silicon melt is between 30-80 mm. In one embodiment, the distance from the wave trough to the liquid level of the silicon melt is 30 mm, and the distance from the wave crest to the liquid level of the silicon melt is 50 mm.

According to an embodiment of the present invention, the deflector comprises a tuning device for tuning the distance between the bottom of the deflector and the liquid level of the silicon melt. The distance between the bottom of the deflector and the silicon ingot is changed via an additional tuning device, which can simplify the process of the deflector on the existing structure of the deflector.

For example, the deflector comprises an inner cylinder, an outer cylinder and a heat-insulation material, in which a bottom of the outer cylinder is extended below a bottom of the inner cylinder and is closed with the bottom of the inner cylinder to form a cavity between the inner cylinder and the outer cylinder, and the heat-insulation material is disposed in the cavity. According to one embodiment of the present invention, the tuning device comprises an insert part, in which the inset part comprises a protruding portion and an insert portion, the insert portion is inserted into the bottom of the outer cylinder and extended to the location between the portion below the bottom of the inner cylinder and the bottom of the inner cylinder, and the protruding portion is extended exceeding the bottom of the inner cylinder. Since the existing deflector is generally configured as a conical barrel type, the bottom of the deflector is usually arranged in a circular cross-section. By setting the deflector to comprise the insertion part between the inner cylinder and the outer cylinder, the shape of the bottom of the deflector can be flexibly tuned by tuning the structure and shape of the insertion part without changing the structure of the existing deflector to tune the distance between the bottom of the deflector and the liquid level of the silicon melt. Therefore, without changing the existing semiconductor crystal growth apparatus, the tuning device with an insertion part is provided to achieve the effect of the present invention. At the same time, the insertion part can be manufactured and replaced in a modular manner, thereby adapting to the growth process of semiconductor crystals in different sizes and different situations for saving costs.

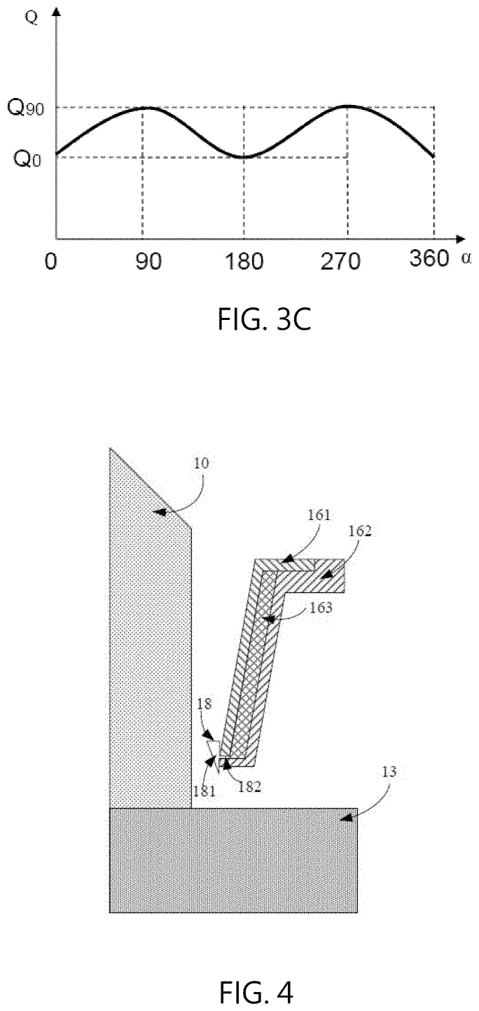

Referring to FIG. 4, FIG. 4 is a schematic structural diagram of the deflector in the semiconductor crystal growth apparatus. The deflector 16 may comprise an inner cylinder 161, an outer cylinder 162 and a heat-insulation material 163, in which a bottom of the outer cylinder 162 may be extended below a bottom of the inner cylinder 161 and be closed with the bottom of the inner cylinder 161 to form a cavity between the inner cylinder 161 and the outer cylinder 162, and the heat-insulation material 163 may be disposed in the cavity. The deflector 16 may be configured to comprise an inner cylinder, an outer cylinder, and a heat-insulation material 163, which can simplify the installation of the deflector. For example, the material of the inner cylinder and the outer cylinder may be graphite, and the heat insulation material may comprise glass fiber, asbestos, rock wool, silicate, aerogel felt, vacuum board, and the like.

Referring to FIG. 4, a tuning device 18 may be provided at the lower end of the deflector 16. The tuning device 18 may comprise a protruding portion 181 and an insertion portion 182 provided to be inserted into the bottom of the outer cylinder 162 extending a position between a portion below the bottom of the inner cylinder 161 and the bottom of the inner cylinder 161. The tuning device is installed on the deflector in an inserted form, without the need to modify the deflector, the installation of the tuning device can be achieved, further simplifying the manufacturing and installation costs of the tuning device and the deflector. At the same time, the insertion part may be inserted between the bottom of the outer cylinder and the bottom of the inner cylinder, which effectively reduces the heat conduction from the outer cylinder to the inner cylinder, lowers the temperature of the inner cylinder, and further reduces the radiant heat transfer from the inner cylinder to the crystal ingot, reduces the difference of the axial temperature gradient between of the center and the periphery of the silicon ingot, and improves the quality of crystal pulling. For example, the tuning device may be arranged to a material with low thermal conductivity, such as SiC ceramic, quartz, etc.

For example, the tuning device may be arranged in sections, such as two sections on the deflector in a direction perpendicular to the direction of the magnetic field, or may be arranged along the circumference of the bottom of the deflector, such as a ring. Further, for example, the ring may be provided with a wave-shaped surface protruding downward at the bottom.

It should be understood that the setting of the tuning device in sections or in the shape of a ring is only exemplary, and any tuning device capable of tuning the distance between the bottom of the inner cylinder of the deflector and the silicon ingot is suitable for the present invention.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor crystal growth apparatus, comprising:
a furnace body;
a crucible, disposed inside the furnace body for containing a silicon melt;
a pulling device, disposed on the top of the furnace body for pulling a silicon ingot from the silicon melt;
a deflector, in a barrel shape and disposed in the furnace body in a vertical direction; and
a magnetic field applying device, configured to apply a horizontal magnetic field to the silicon melt in the crucible; wherein the distance between the bottom of the deflector and the liquid level of the silicon melt in the direction of the magnetic field is less than that between the bottom of the deflector and the silicon melt in the direction perpendicular to the direction of the magnetic field.

2. The apparatus according to claim 1, wherein the bottom of the deflector has a wave-shaped surface protruding downward.

3. The apparatus according to claim 2, wherein in the direction of the magnetic field, the bottom of the deflector is located on a wave trough of the wave-shaped surface, such that the distance between the bottom of the deflector and the liquid level of the silicon melt in the direction of the magnetic field is minimum, and in the direction perpendicular to the direction of the magnetic field, the bottom of the deflector is located on a wave crest of the wave-shaped surface, such that the distance between the bottom of the deflector and the liquid level of the silicon melt in the direction of the magnetic field is maximum.

4. The apparatus according to claim 3, wherein the distance between the wave trough of the wave-shaped surface and the liquid level of the silicon melt is between 10-50 mm, and the distance between the wave crest of the wave-shaped surface and the liquid level of the silicon melt is between 30-80 mm.

5. The apparatus according to claim 1, wherein the deflector comprises a tuning device, which is configured to tune the distance between the deflector and the liquid level of the silicon melt.

6. The apparatus according to claim 5, wherein the deflector comprises an inner cylinder, an outer cylinder and a heat-insulation material, in which a bottom of the outer cylinder is extended below a bottom of the inner cylinder and is closed with the bottom of the inner cylinder to form a cavity between the inner cylinder and the outer cylinder, the heat-insulation material is disposed in the cavity, the tuning device comprises an insert part, in which the inset part comprises a protruding portion and an insert portion, the insert portion is inserted into the bottom of the outer cylinder and extended to the location between the portion below the bottom of the inner cylinder and the bottom of the inner cylinder, and the protruding portion is extended exceeding the bottom of the inner cylinder.

7. The apparatus according to claim 6, wherein the tuning device comprises at least two sections disposed along a direction perpendicular to the direction of the magnetic field.

8. The apparatus according to claim 6, wherein the protruding portion is arranged as a ring.

9. The apparatus according to claim 8, wherein the bottom of the ring has a wave-shaped surface protruding downward.
